(19) United States
(12) Patent Application Publication
(10) Pub. No.: US 2023/0193003 A1
(43) Pub. Date: Jun. 22, 2023

(54) POLYMER BLENDS FOR MICROENVIRONMENTS

(71) Applicant: ENTEGRIS, INC., Billerica, MA (US)

(72) Inventor: Alissa A. Wild, Chaska, MN (US)

(21) Appl. No.: 18/084,213

(22) Filed: Dec. 19, 2022

Related U.S. Application Data
(60) Provisional application No. 63/292,886, filed on Dec. 22, 2021.

(51) Int. Cl. C08L 23/08; C08K 3/04; B82Y 30/00

(52) U.S. Cl. CPC C08L 23/0823; C08K 3/041; B82Y 30/00; C08K 2201/011; C08L 2207/04

(57) ABSTRACT

A microenvironment including a shell structure, the shell structure configured to hold semiconductor wafers, wherein the microenvironment includes a blend of cyclo olefin copolymer and one or more polyolefin polymers. The blend may further include a conductive material, such as carbon nanotubes to enhance conductivity of the blend. The blend may be free of impact agents, mold release agents, and plasticizers.

### PRIORITY

This disclosure claims priority to U.S. provisional patent No. 63/292,886, with a filing date of Dec. 22, 2021, which is incorporated by reference herein for all purposes.

### FIELD

This disclosure concerns polymer blends for forming microenvironments. Specifically, polymer blends which include cyclo olefin copolymer (COC) and a polyolefin polymer. The polyolefin may be a polyolefin, a cyclic olefin copolymer elastomer, or a thermoplastic olefin elastomer. The microenvironments may include front opening unified pods (FOUPs).

### BACKGROUND

Microenvironments for storing semiconductor wafers and reticles require a combination of strength, cleanliness, and conductivity. Examples of these containers include front opening unified (or universal) pods (FOUPs). FOUPs protect semiconductor wafers during storage and transportation. FOUPs and similar microenvironments may control the environment used to store the wafers or other sensitive components. For example, a FOUP may be purged with nitrogen or another gas to reduce the oxygen or water level (humidity) of the environment inside the FOUP. Additionally, FOUPs may be conductive to reduce the accumulation of static charge to protect the sensitive wafers or reticles contained therein.

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise. As used in this specification, the term “about” is generally used to include +/−5% of the value included therewith.

The scope of the disclosure should be determined by the appended claims and their legal equivalents, rather than by the examples given herein. For example, the steps recited in any method claims can be executed in any order and are not limited to the order presented in the claims. Moreover, no element is essential to the practice of the disclosure unless specifically described herein as “critical” or “essential.”

Cyclo olefin copolymers (COCs) have excellent optical properties including high transmission and are generally clean materials with low outgassing. Outgassing is the release of material from the shell and structure which may contaminate clean wafers. Outgassing may be organics or low molecular weight components of the polymer. Examples of outgassing can include additives to polymers (e.g., plasticizers, mold release agents, etc.) as well as low molecular weight components, such as oligomers, in the polymer.

However, COCs may require modification in order to provide the desired properties for microenvironments. Further, some blends of COCs with impact agents have resulted in polymer blends with unacceptable levels of outgassing. COCs are candidates for materials for FOUPs and other highly clean shells and components. However, the lack of impact strength and relatively low elongation at break have limited the use of COCs in these applications.

Applicant's solution to the challenges posed with COCs for FOUPs and similar microenvironments is to create a compound, e.g., melt blend, of the COC with a polyolefin. COC enjoys good matrix formation compatibility with polyolefins. The blending of COC and polyolefin may improve melt processing compared with the COC alone. In some examples, the COC is heated and blended and then the polyolefin is added to the COC to form a blend. A variety of polyolefins are suitable for blending with COC, for example, polyethylene (e.g., HDPE), polypropylene (PP), thermopolyolefins (TPO), polyolefin elastomers (POE), cyclic polyolefin elastomer, and blends thereof. In an embodiment, the addition of the polyolefin increases the ductility and reduces the hardness of the COC. In some embodiments, the polyolefin is a polyolefin elastomer. In an embodiment, the polyolefin is a cyclo olefin elastomer. Some examples of polyolefin elastomers include, but are not limited to, polyisobutylene (PIB), poly(a-olefin)s, ethylene propylene rubber (EPR), and ethylene propylene diene monomer (M-class) rubber (EPDM rubber). The polyolefin may be 1% to 40% by weight of the blend of polyolefin and COC. In an embodiment, the polyolefin may be 5% to 20% by weight of the blend of polyolefin and COC.

The formation of FOUPs from a blend of COC and polyolefin offers several advantages. There are a variety of suitable polyolefins which can be melt processed. Suitable polyolefins have a variety of molecular weight distributions with a variety of properties. For example, the polyolefin may be a polyolefin elastomer. Polyolefins have good compatibility with the COC. This allows a variety of blends with the respective properties being a function of the specific blend. This ability to tune the properties of the resulting blend provides flexibility in the design of the material for the FOUPs. Specifically, the blend can have higher amounts of polyolefin to provide greater impact strength and flexibility. The blend can have higher amounts of COC to provide stiffness and tensile strength, and to adjust the glass transition temperature of the blend. In some embodiments, the polyolefin is a plurality of polyolefins. For example, the polyolefins may include both HDPE and a cyclo olefin elastomer.

The blend may include a conductivity enhancing agent such as carbon nanotubes, carbon black, carbon fiber, etc. In an embodiment, carbon nanotubes make up 5% or less by weight of the blend. In another embodiment, carbon black makes up 10% to 20% by weight of the blend. When used, carbon fiber may be up to 15% by weight of the blend.

In some embodiments, impact modifiers may be used in the blend, for example, up to 15% by weight of the blend. Suitable impact modifiers include block styrene and/or ethylene block impact modifiers. In some embodiments, an impact modifier is made up of rubber particles in a polyolefin matrix.

In some other embodiments the blend is free of impact modifiers. For example, the blend may be made of the combination of COC, one or more polyolefins, and a conductivity enhancing agent without additional materials. The blend may be free of plasticizers. The blend may be free of mold release agents.

The blend may be compounded and injection molded using conventional processes. Compounding may be performed using a twin-screw compounder and the resulting blend pelletized. In an embodiment, the COC is provided at the input and the polyolefin is added later to the melt. Similarly, the conductive component, impact modifier, or combinations thereof of the blend may be added to the melt at a later point in the compounding process. The molding may then be conducted with a single screw molding system.

The blend may be used to mold components (e.g., shells, doors) of microenvironments. The microenvironments described may include FOUPs or reticle pods. In some embodiments, the microenvironments are designed to provide mechanical and electrical protection for semiconductor wafers during processing. The microenvironments may be used for storage and/or transportation of wafers or other sensitive components.

The disclosed blend of COCs and polyolefins reduces outgassing in the molded microenvironments. In some embodiments, the blend has an outgassing below 1 microgram per gram. The blend may have lower outgassing, for example, below 500 nanograms per gram. Lower outgassing is associated with reduced contamination of materials stored in the microenvironment.

The disclosed blend of COCs and polyolefins can improve strength characteristics in the resulting microenvironments. In some embodiments, the blend has an Izod notched impact strength of at least 60 joules per meter. The blend may have an Izod notched impact strength of 90 joules per meter. The impact strength may be tested according to ASTM D 256. Higher impact strengths may be beneficial for the mechanical strength of the microenvironment.

In some embodiments, the blend has a surface resistivity of 1E5 to 1E10 ohm/sq. Surface resistivity may be measured according to ASTM D 257. A low surface resistivity may facilitate electrostatic discharge, thereby protecting the components in the microenvironment.

In some embodiments, the blend has a melt flow rate (MFR) between 2 and 9 grams per 10 minute at 280° C. and 6.7 kg. Control of melt flow rate may be important for molding of the microenvironments.

In some embodiments, the blend has a specific gravity of about 1.01. In some examples, molded components with higher specific gravities performed better than components with lower specific gravities. The specific gravity may be measured using ASTM 792.

Another useful test is mold shrinkage as assessed by ASTM D955. In some embodiments, the mold shrinkage is less than 1.0%, for example, about 0.5% or between 0.3% and 0.7%.

In some embodiments, the tensile strength, tensile modulus, and elongation at break are useful data with higher tensile strengths, higher tensile modulus, and larger elongation at break being favored. These two requirements tend to work against each other as higher tensile strength is often associated with reduced elongation at break. However, it may be desirable to maintain a level of elongation at break so that the material has ductility and is impact resistant. Testing of these factors may be conductive according to ASTM D638. The inclusion of polyolefin material in the blend may increase the ductility and the elongation at break.

In some embodiments, flex strength and flex modulus may be useful parameters to measure when evaluating microenvironments. Generally greater flex strength and greater flex modulus are preferred.

In an embodiment, a blend may include 69 to 82 wt. % cyclo olefin copolymer. The blend may include 15 to 20 wt. % polyolefin. The blend may further include 2 to 6 wt. % olefin block copolymer and 1 to 5 wt. % carbon nanotubes. Testing of blends in these ranges provided formulations with excellent mechanical, molding, and other properties suitable for making microenvironments. In some examples, these were substantially all the components of the formulation, i.e., no mold release, no impact agent, etc. In some embodiments, the blend consists of the formulation described above without additional components.

In an embodiment, a blend includes about 76.75 wt. % cyclo olefin copolymer, about 18 wt. % polyolefin, about 2.5 wt. % olefin block copolymer, and about 2.75 wt. % carbon nanotubes. The blend may be substantially free of other components. In some embodiments, the blend consists of the described components. The blend may provide a desirable combination of flexibility, strength, and cleanliness suitable for microenvironments.

### Aspects

Any of aspects 1-9 may be combined with aspects 10-13 or 14-15. Any of aspects 10-13 may be combined with aspects 14-15.

Aspect 1: An article comprising a microenvironment including: a shell structure, the shell structure configured to hold semiconductor wafers, wherein the microenvironment comprises a blend of cyclo olefin copolymer and one or more polyolefin polymers.

Aspect 2: The article of aspect 1, wherein the one or more polyolefin polymers are selected from a group consisting of high-density polyethylene (HDPE), polyethylene (PE), polypropylene (PP), thermopolyolefin (TPO), polyolefin elastomer (POE), and mixtures thereof.

Aspect 3: The article of aspect 1 or 2, wherein the one or more polyolefin polymer comprises 1% to 40% by weight of the blend of cyclo olefin copolymer and polyolefin polymer.

Aspect 4: The article of any of aspects 1-3, wherein the microenvironment is a front opening unified pod (FOUP).

Aspect 5: The article of any of aspects 1-4, wherein the blend further comprises a conductivity enhancing agent.

Aspect 6: The article of aspect 5, wherein the conductivity enhancing agent comprise carbon nanotubes.

Aspect 7: The article of any of aspects 1-6, wherein the blend has an elongation at break of at least 5% as measured by ASTM D 638.

Aspect 8: The article of any of aspects 1-7, wherein the blend has an outgassing below 1 microgram per gram.

Aspect 9: The article of any of aspects 1-8, wherein the blend is substantially free of impact modifying agent.

Aspect 10: An article comprising a front opening unified pod (FOUP) comprising a blend of cyclo olefin copolymer and polyolefin polymer wherein the blend includes 1% to 40% by weight of polyolefin polymer and the blend has an outgassing below 1 microgram per gram.

Aspect 11: The article of claim 10 wherein the blend consists essentially of cyclo olefin copolymer, polyolefin polymer, and carbon nanotubes.

Aspect 12: The article of aspect 10 or 11, wherein the blend has an elongation at break of at least 5% as measured by ASTM D 638.

Aspect 13: The article of any of aspects 10-12, wherein the blend has a surface resistivity of 1E5 to 1E10 ohm/sq as measured by ASTM D 257.

Aspect 14: A method comprising injection molding a blend of a cyclo olefin copolymer and one or more polyolefin polymers to form a shell of a microenvironment.

Aspect 15: The method of aspect 14 wherein the one or more polyolefin polymer comprises a polyolefin elastomer.

What is claimed is:

1. An article comprising a microenvironment including:
a shell structure, the shell structure configured to hold semiconductor wafers, wherein the microenvironment comprises a blend of cyclo olefin copolymer and one or more polyolefin polymers.

2. The article of claim 1, wherein the one or more polyolefin polymers are selected from a group consisting of high-density polyethylene (HDPE), polyethylene (PE), polypropylene (PP), thermopolyolefin (TPO), polyolefin elastomer (POE), and mixtures thereof.

3. The article of claim 1, wherein the one or more polyolefin polymer comprises 1% to 40% by weight of the blend of cyclo olefin copolymer and polyolefin polymer.

4. The article of claim 1, wherein the microenvironment is a front opening unified pod (FOUP).

5. The article of claim 1, wherein the blend further comprises a conductivity enhancing agent.

6. The article of claim 5, wherein the conductivity enhancing agent comprise carbon nanotubes.

7. The article of claim 1, wherein the blend has an elongation at break of at least 5% as measured by ASTM D 638.

8. The article of claim 1, wherein the blend has an outgassing below 1 microgram per gram.

9. The article of claim 1, wherein the blend is substantially free of impact modifying agent.

10. An article comprising a front opening unified pod (FOUP) comprising a blend of cyclo olefin copolymer and polyolefin polymer wherein the blend includes 1% to 40% by weight of polyolefin polymer and the blend has an outgassing below 1 microgram per gram.

11. The article of claim 10 wherein the blend consists essentially of cyclo olefin copolymer, polyolefin polymer, and carbon nanotubes.

12. The article of claim 10, wherein the blend has an elongation at break of at least 5% as measured by ASTM D 638.

13. The article of claim 10 wherein the blend has a surface resistivity of 1E5 to 1E10 ohm/sq as measured by ASTM D 257.

14. A method comprising injection molding a blend of a cyclo olefin copolymer and one or more polyolefin polymers to form a shell of a microenvironment.

15. The method of claim 14 wherein the one or more polyolefin polymer comprises a polyolefin elastomer.
